(19) United States
(12) Patent Application Publication
(10) Pub. No.: US 2012/0091307 A1
(43) Pub. Date: Apr. 19, 2012

(54) STAND AND METHOD FOR HANDS FREE READING AND VIEWING

(76) Inventor: Debra Haynes, Costa Mesa, CA (US)

(21) Appl. No.: 13/026,486

(22) Filed: Feb. 14, 2011

Related U.S. Application Data
(60) Provisional application No. 61/392,903, filed on Oct. 13, 2010.

(51) Int. Cl. H05K 7/00

(52) U.S. Cl. 248/451

(57) ABSTRACT

A flexible stand for an electronic reading device allows hands-free support with infinitely adjustable positioning in three dimensions plus an additional degree of pivot-ability. Using flexible tubing (gooseneck tubing) of two of more degrees of flexibility allows a stiffer portion to act as a stable but grossly repositionable base. In a complementary fashion, a more flexible portion proximal to the supported reading device allows for ready fine positioning.

In addition a pivot joint provides for altering the plane of the viewing screen in an additional freedom of movement not easily provided by the flexible tubes.

### RELATED APPLICATIONS

This application claims priority from U.S. provisional application 61/392,903, filed Oct. 13, 2010, which is hereby incorporated herein by reference in its entirety.

### FIELD

This invention relates generally to a positionally adjustable support for electronic reading and viewing devices and support of other objects that provide a source of information or entertainment.

### BACKGROUND

When reading for prolonged periods of time people continually change positions, slightly or significantly. This requires that the position of the reading material be adjusted as well such that a comfortable focal length and orientation of the reading material to the eyes is maintained. When holding a book, or an electronic book, normally such positional adjustment occurs naturally and without thought. There are situations in which attaining and maintaining a comfortable reading position can be difficult.

Portable viewable devices that are normally handheld such as visual display electronic devices, e.g. the Kindle, the iPad, similar computers, and electronic readers depend upon the user to hold the device at the appropriate position. This typically means that one's hands are not free for some other activity. For some handicapped persons these devices are either not usable or very inconvenient to use. A variety of holders have been proposed including one described in published U.S. utility application 2008/0087789, Haynes. Although primarily for books, Haynes teaches a flexible reading stand constructed from a flexible tube, also called a “gooseneck” tube. While that teaching solves some of the above issues it forces a trade-off between supporting strength and ease of repositioning.

### SUMMARY

Some embodiments consistent with the teachings herein include reading stands comprised of tubes having different degrees of flexibility along their length. A more flexible type of tubing can be used close to the position of the viewing screen to allow convenient fine repositioning and orienting of the reading surface. A less flexible tubing can be used for most other portions of a stand to provide for a stronger overall support. Some versions can hold books. Some versions can have bases, clamps, and other anchoring structures. Still other versions can be self-standing supported by the partial coiling of relatively inflexible, flexible tubing at the distal end. Embodiments can include detachable portions, continuous tubing of varying stiffness, and can include multiple tubes of different characteristics coupled to one another.

### BRIEF OVERVIEW OF THE DRAWINGS

FIG. 1 shows a first example stand embodiment in a perspective view;

FIG. 2 shows an exploded view of the first example embodiment;

FIG. 3 shows the first example unit showing an electronic book reader being inserted;

FIG. 4 is a perspective view of the back of the first example unit;

FIG. 5 shows the rear view of a stand that is a variation of the stand of FIG. 1;

FIG. 6 is the partial, exploded, perspective view of the tube-to-holder attachment of the unit of FIG. 5;

FIG. 7 is an exploded view of a region of FIG. 5 showing an alternate upper-tube-to-lower-tube coupling;

FIGS. 8A-8D are perspective drawings of the unit of FIG. 1 in various usage orientations;

FIG. 8E is an alternate “landscape” variation of the unit of FIG. 1;

FIG. 9 shows a user grasping the lower, stiffer, tubing in making a gross repositioning;

FIG. 10 shows a user grasping the holder portion to make a fine repositioning;

FIGS. 11-16 are pictorial representations of various usage modes of the unit of FIG. 1;

FIG. 17 is a perspective view of a second example ebook stand;

FIG. 18 is an exploded view of a region of FIG. 17 showing its quick disconnect coupling;

FIG. 19 is the unit of FIG. 17 in which the lower thicker tube has been disconnected;

FIG. 20 shows a third example stand with externally uniform tubing;

FIG. 21 is an expanded, partial cutaway, view of a region of FIG. 20 along the line 21-21;

FIG. 22 is a front perspective view of an alternate holder that accommodates readers of varying widths;

FIG. 23 shows a rear perspective view of the unit of FIG. 22;

FIG. 24A shows a fourth example unit designed to accommodate a smaller size device;

FIG. 24B shows the unit of FIG. 24A with a small device in it;

FIG. 25 shows a perspective view of an alternate holder seen from the rear;

FIG. 26 shows a version of a stand with a fabric sleeve over the tube.

### DETAILED DESCRIPTION

Embodiments of the teachings herein can have a holder portion and a stand portion.

### FIRST EXAMPLE

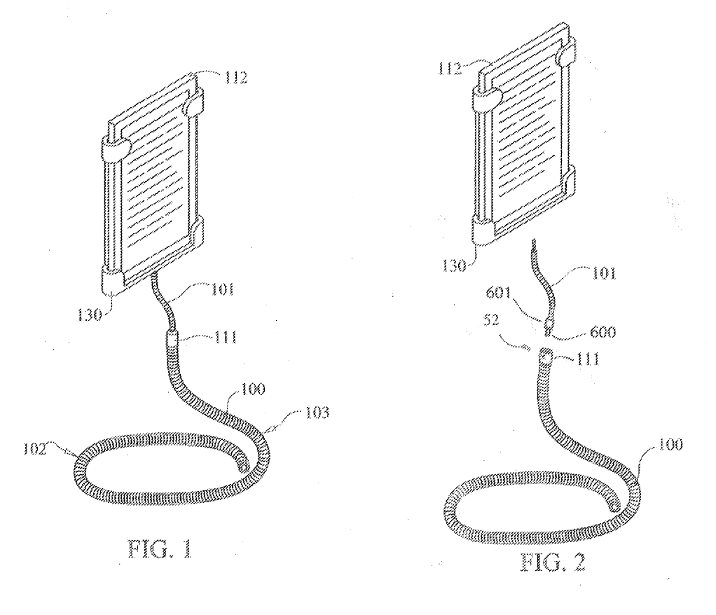

As shown in the example embodiment of FIG. 1, the stand portion can be constructed of two distinct tube portions each of a different diameter and a different degree of flexibility. The tube portion 101 closer to the holder 130 is of thinner, more flexible tubing, while the remainder of the tubing 100 has a reduced degree of flexibility in order to provide a stable base region 102 and sturdy stand region 103.

One source for tubing as shown in FIG. 1 is Spiral Metal Products Division of Uniprise International, Inc. located in Terryville, Conn., which offers flexible metal tubing in diameters from less than ¼″ to over ½″. They rate degrees of flexibility in terms of a tube's minimum bend radius. Those offered include tubes ranging from a bend radius of 1″ to 6″. Another source is Vermont Flexible Tubing Company of Lyndonville, Vt., that offers a similar product range.

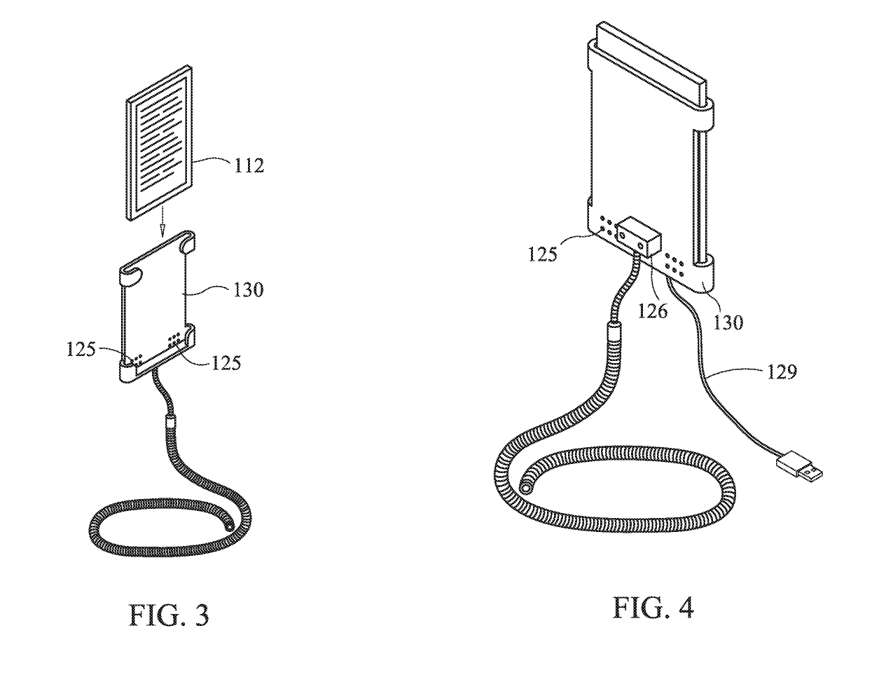

In the exploded view of FIG. 2, this first example version is clearly seen to comprise two distinct lengths of tubing types. One is thicker and stiffer 100 the other is thinner and more flexible 101. They are interconnected by a short threaded tube 600, extending from the upper fitting 601 that is screwed into a threaded receptacle 111 comprising the lower fitting. As shown, they are prevented from unscrewing by a setscrew 52. Alternatively, a thread locking substance can be used. The holder 130 shown in this version is particularly adapted for holding a thin electronic book reader 112. The holder in this version is of a fixed size appropriate to snuggly accept the book reader as it is slid in from above as seen in FIG. 3. Also depicted in FIG. 3 are arrays of small holes 125 designed to align with speakers in the rear of the book reader. In some versions a snug fit is provided by a portion of the holder comprising an elastomeric material. It is constituted so as to provide a friction fit that is readily overcomeable during insertion and removal of an ebook reader. This might be by a flat pad or by dots or strips of an elastomeric material.

As seen in the partial, expanded rear view of FIG. 4, the holder 130 is held to the proximate portion of the tube by a pivotable joint 126. In this example the joint provides a degree of friction that allows ready pivoting by a user but is sufficient to hold the moment of the holder and the held electronic reader that it is designed to accommodate. Also shown in this figure is a charging cord 129 plugged into the ebook through an optional opening (not visible in this view) in the bottom of the holder. A holder can be comprised of injection molded plastic parts or can be constructed of metal or other suitable materials.

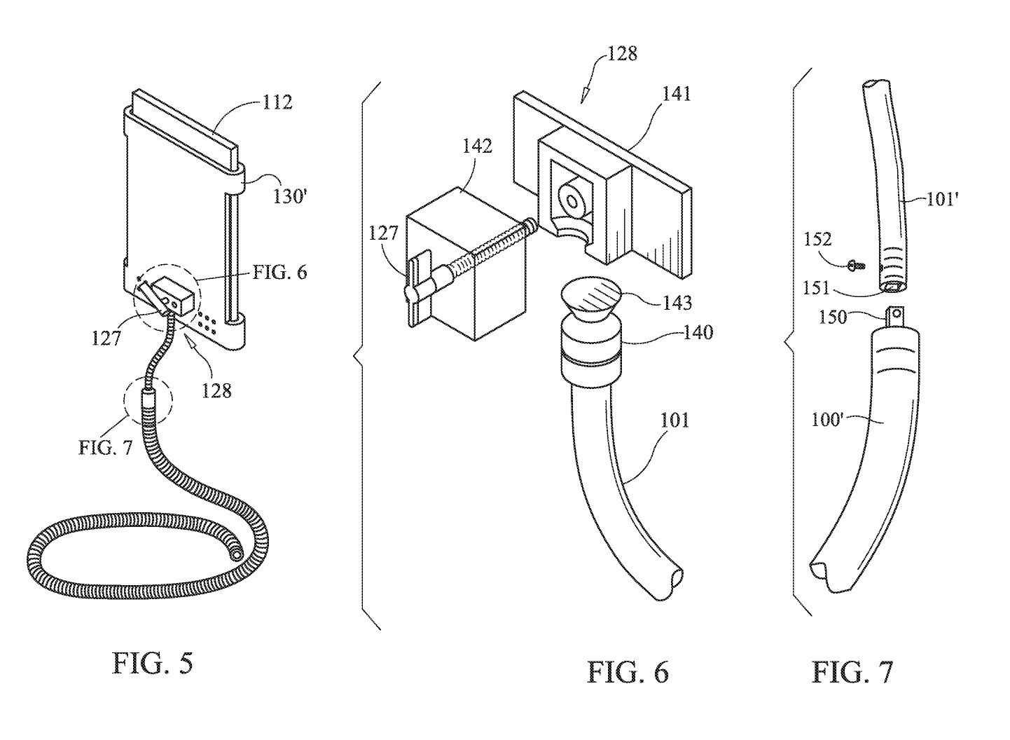

An alternate coupling 128 of a holder 130′ to tubing is shown in FIG. 5 and FIG. 6. In this version, a locking knob 127 is provided to allow variation in the joint's friction. The tube 101 is terminated in an end 140 with an upside down frustum-shaped upper portion 143. That upper portion is clamped between a block 142 that holds the locking knob and a second block 141 attached to the rear of the holder. Due to the complimentary shapes of the interior of the blocks, pivoting is provided for. Tightening the locking knob holds it in position. Stands designed to support heavier objects might benefit from this approach.

An alternate connection of a thinner, more flexible tube 101′ and a thicker, less flexible tube 100′ is seen exploded and expanded in FIG. 7. In this interconnection a setscrew 152 is used to mutually secure the two tubes 100′ 101′. These tubes are coupled to each other by corresponding male 150 and female 151 squared connecting features.

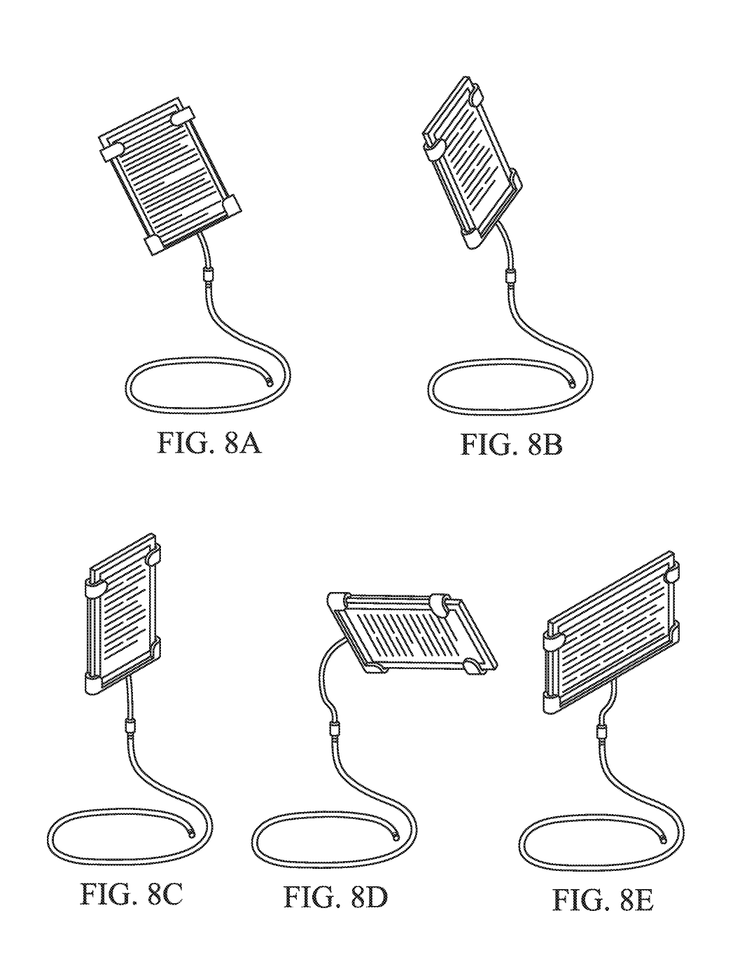

Several illustrations of this first example are seen in FIGS. 8A-8D. An alternate version is seen in use in FIG. 8E. This figure shows a holder in a landscape position. The version depicted in FIG. 8E could be provided for by a swivel capability in the tube-to-holder connection of the first example. In this case the swivel would be more centered on the holder. Alternatively, the teachings herein are broad enough to encompass a holder variation with a landscape orientation for some ebook readers. Shown in FIG. 8D, the reader is turned approximately 90 degrees from its orientation in FIG. 8C and is in a position suitable for reading while lying down on one's side.

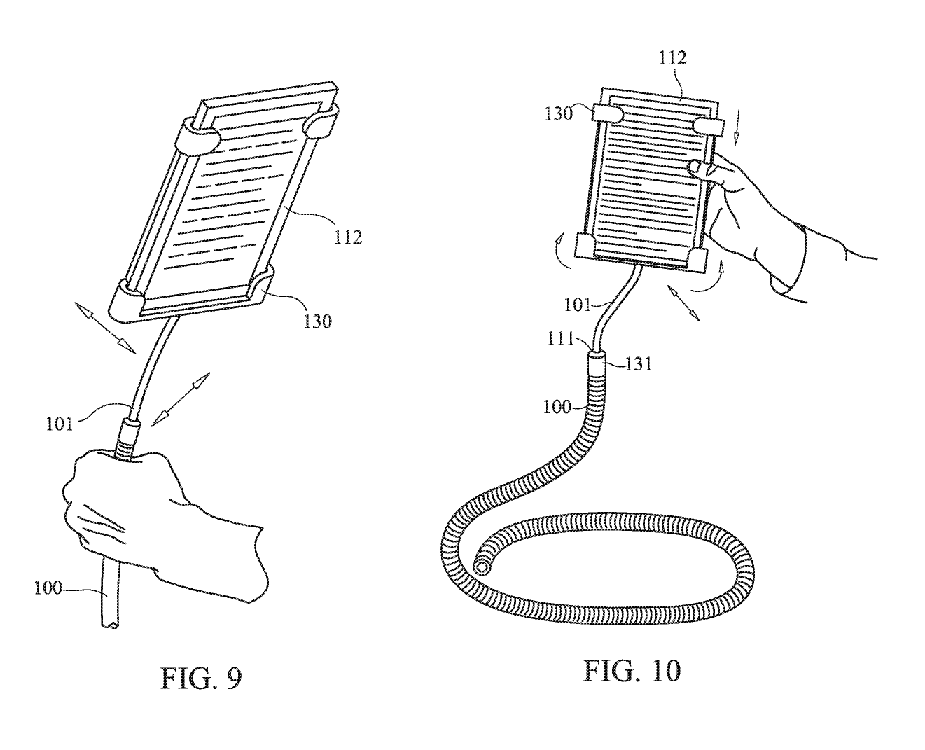

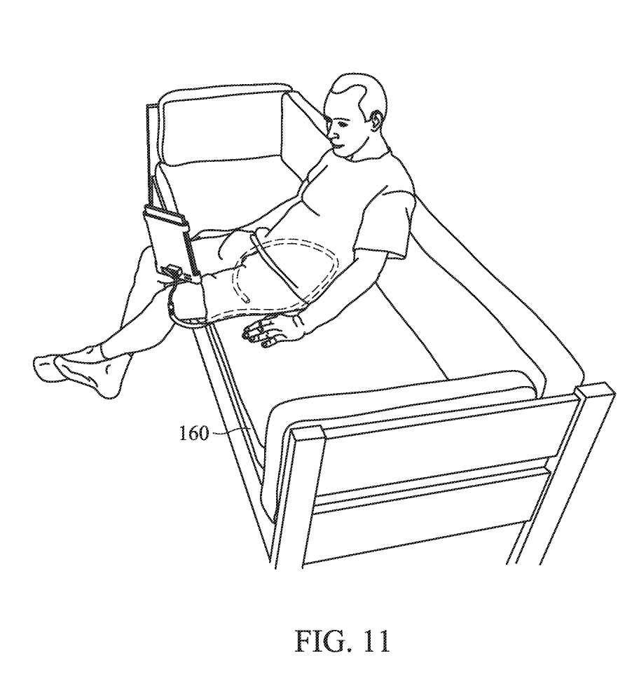

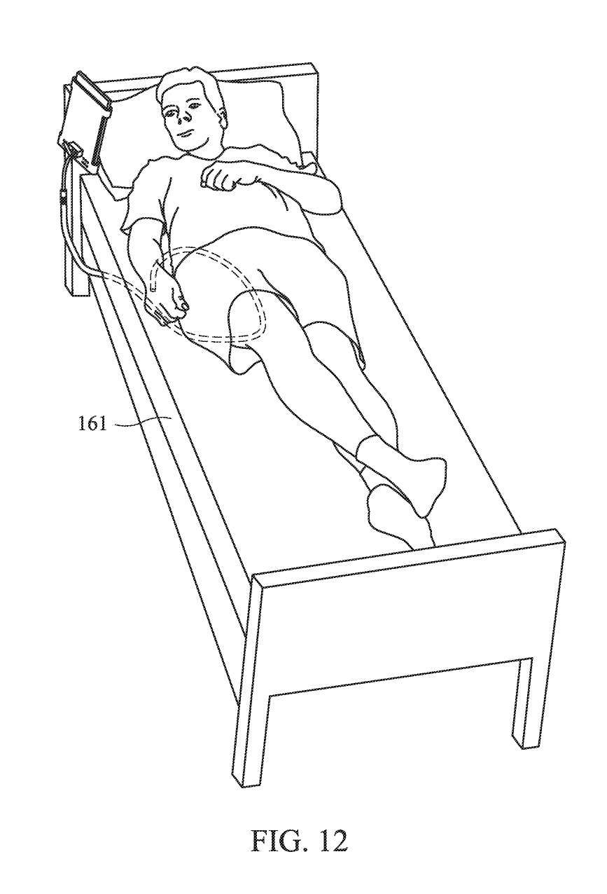

A gross positioning adjustment of the first example is illustrated in FIG. 9. The user is shown grasping the less flexible tubing 100 with one hand. This allows general positioning by flexing the lower tube. FIG. 10 depicts a fine adjustment. It shows the user moving the holder 130 by grasping the side of it with one hand. This allows flexing the upper tube.

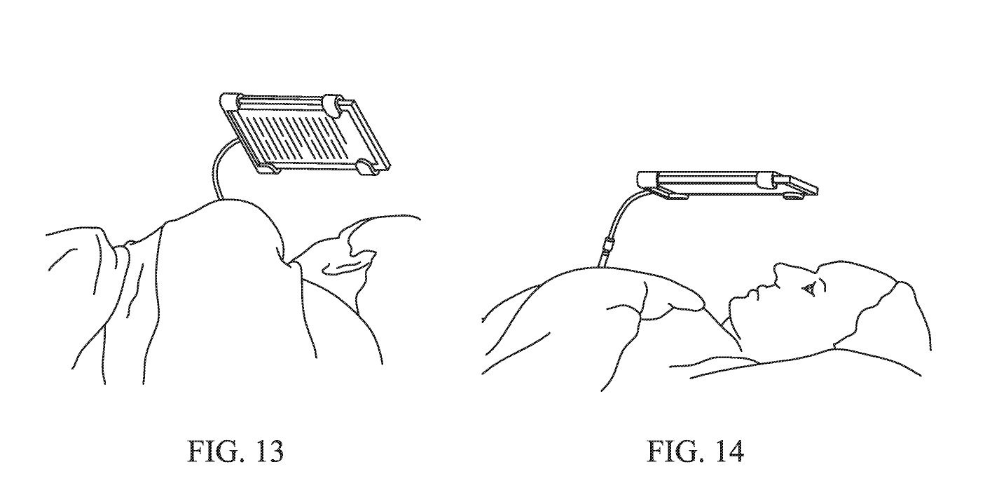

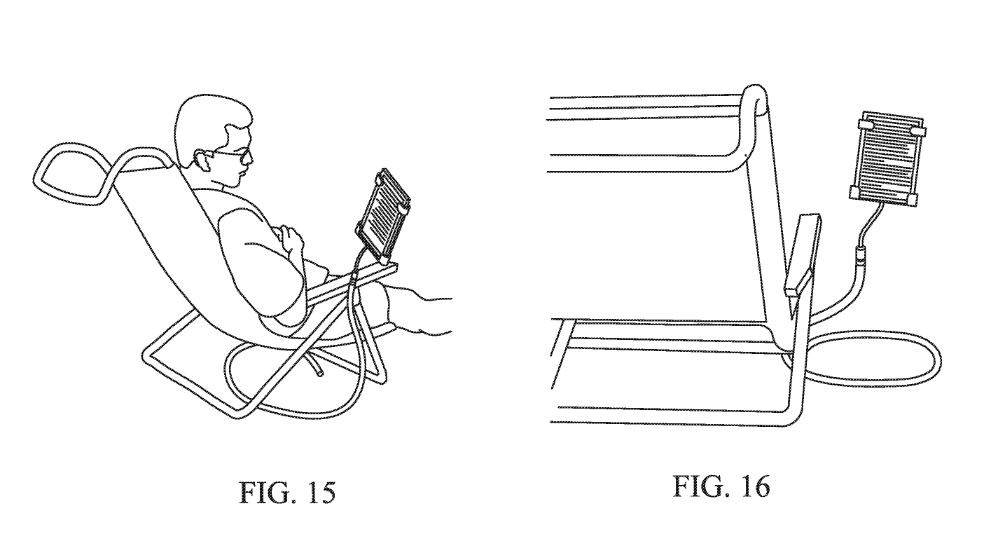

FIGS. 11-16 show the flexibility of applications of an example embodiment stand in a variety of possible positions. FIG. 11 shows a person sitting on a couch reading with a portion of the tubing under the cushion 160 of the couch. FIG. 12 shows a person reading in bed with a portion of the tubing under the mattress 161. In FIGS. 13 and 14 a person is reading in bed with the stand shown in various positions. FIGS. 15 and 16 show a person reading in a beach chair with the stand in various positions. Versions of a holder may also have provisions for integral sunshade flaps or a visor for use outdoors.

### VARIATIONS OF THE FIRST EXAMPLE

Some embodiments can have more than two tube portions of more than two degrees of flexibility. A very long stand might have three sections of increasing stiffness and heaviness as it descends.

### SECOND EXAMPLE

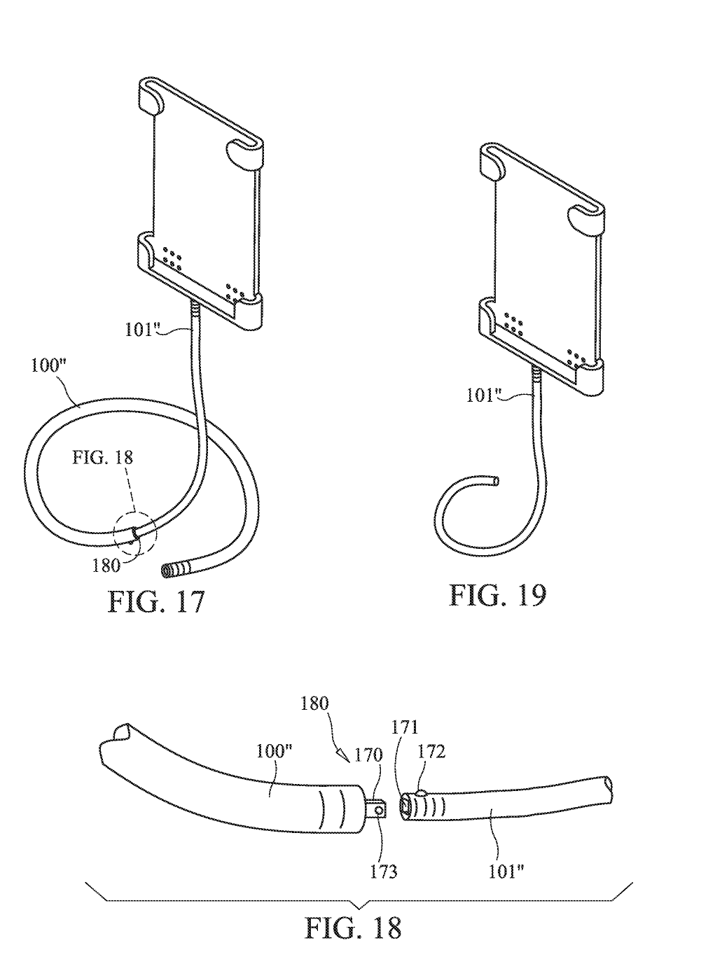

The second example stand, seen in FIG. 17, is also a self-supporting unit and has a thicker tube portion 100″ coiled to form a base at its distal end. With an adequate base formed by a portion of a tube, embodiments of this version may have no need for a further base structure. This example is also comprised of two connected tubes, the thicker, less flexible tube mentioned above and a thinner, more flexible tube 101″. However they are readily user-detachable by pressing a spring-loaded button 172 as seen in the exploded partial view of FIG. 18. The more flexible upper tube portion is relatively long with the joint between more flexible and less flexible tubes essentially further down the stand. It has a squared male end 170 with a spring-loaded ball 173 in the thicker section 100″. The complementary female connection 171 is in the thinner tube 101″. This tube also has the release button 172. This detachability feature and the longer upper tube 101″ can provide for additional usage options. For example, when the lower tube 100″ is removed, the stand with just the upper more flexible portion can be used as a tabletop stand as seen in FIG. 19.

### VARIATION OF THE SECOND EXAMPLE

Various alternate extensions might be used with the quick-connect system of FIGS. 17-19. A heavy base, general-purpose clamp, or a special purpose adapter for mounting in a specific application, might have a compatible quick-connect fitting to which the tube 101″ is attachable.

Flexibility

Although the more flexible tube is shown in the various drawings included herein as thinner than the less flexible tube, in fact these tubes are produced in a wide range of diameter and degree of flexibility. Therefore, some embodiments can have upper tubes and lower tubes of a common diameter but differing degrees of flexibility.

### THIRD EXAMPLE

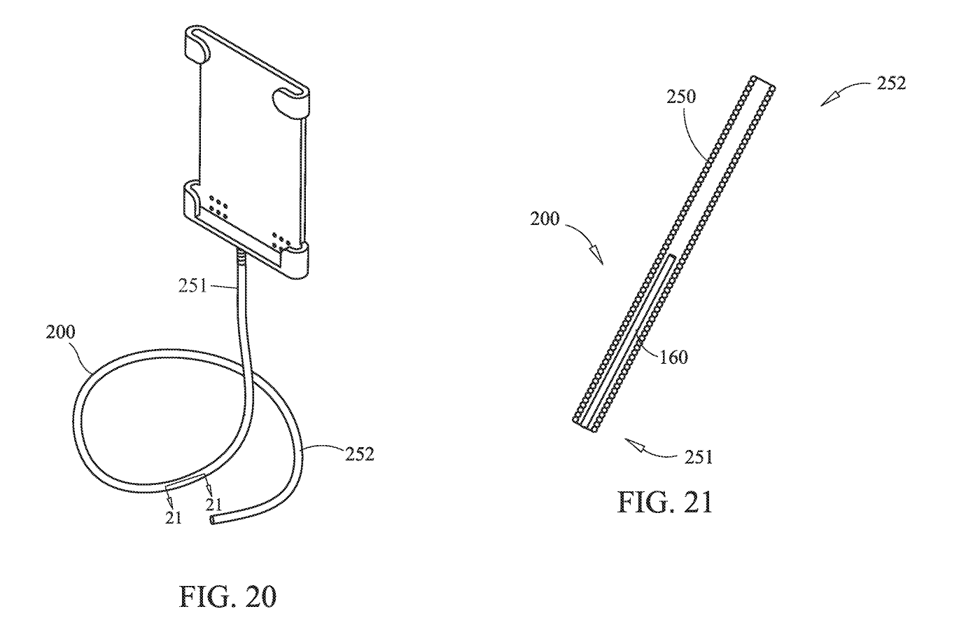

Rather than vary the degree of stiffness/flexibility by discrete, interconnected tubes, other embodiments can use a more integral approach. Shown in FIG. 20 in a usage position, a tube 200 is externally continuous with a uniform diameter.

As seen in FIG. 21 the tube 200 is shown in section that has a solid flexible wire 160 within it. The solid flexible wire extends to a position that represents part of total length of the exterior 250. This configuration provides a tube that has a varying flexibility from stiff at its distal end 251 to more flexible at its proximal end 252 even though the exterior flexible tubing itself is uniform from end to end.

As well as stiffness, the uniformly relatively thin tube of this example may also include additional weight in the most distal portions to contribute to its function as a base. Optionally lead or other material might be included.

Alternate Holder

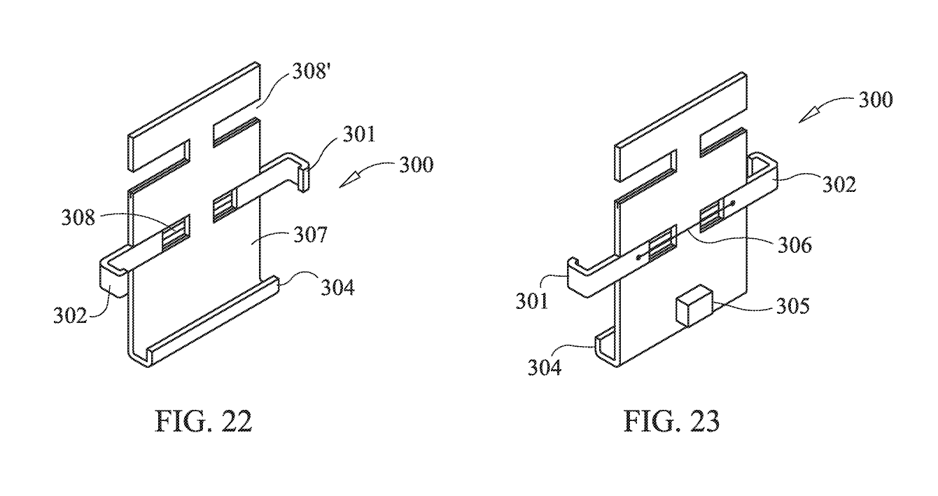

The holder 300 seen in FIGS. 22 and 23 is shown with an upper pair of notches 308′ and a lower pair of notches 308. The holder can be constructed of three generally planar plastic parts. The holder's base 307 has a front lip 304 and two alternate locations for slide pieces 301 302 to be attached. The book reader is captured between the two sliding side pieces that have mutual tension provided by an elastomeric strap 306 (seen on the rear side of the holder in FIG. 23). As shown in FIGS. 22 and 23, the sliding pieces are installed in the lower notches 308. In this version, the sliding pieces could also be repositioned to the upper notches 308′. Alternate positions can provide for access to controls that may be placed in different areas of various devices. The holder also has a pivotable joint 305 for connecting to a flexible tube.

### FOURTH EXAMPLE

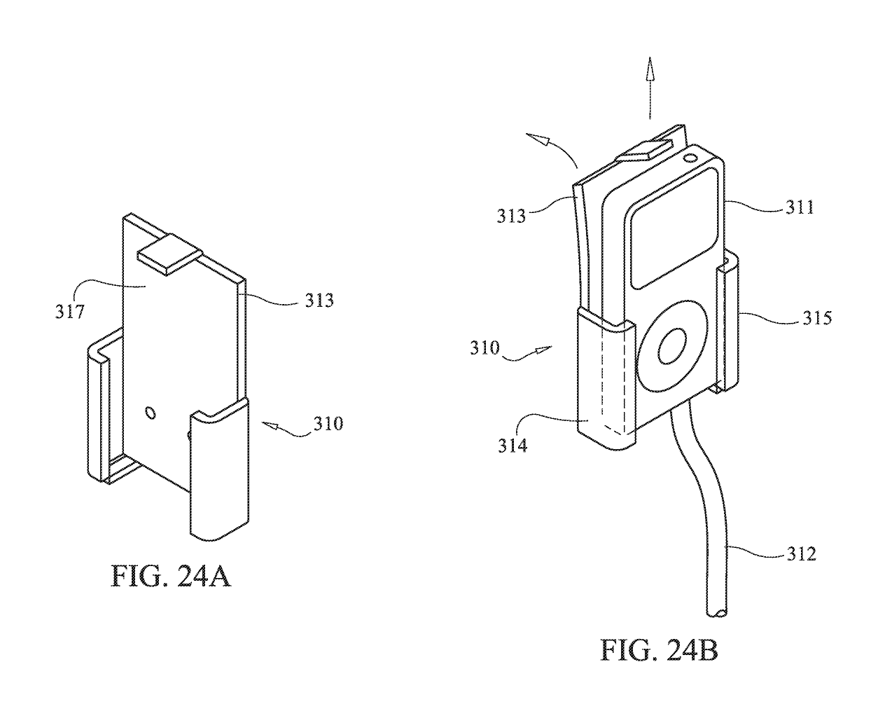

FIGS. 24A and 24B show a version with a small holder 310 adapted for use with an iPod or similar sized device. The upper portion 313 of the base 317 is shown in FIG. 24B in a bent-back position for the insertion or removal of a portable device 311. In this version the device also has retaining sides 314 315. The holder also connects to a flexible tubing 312 as seen in FIG. 24B.

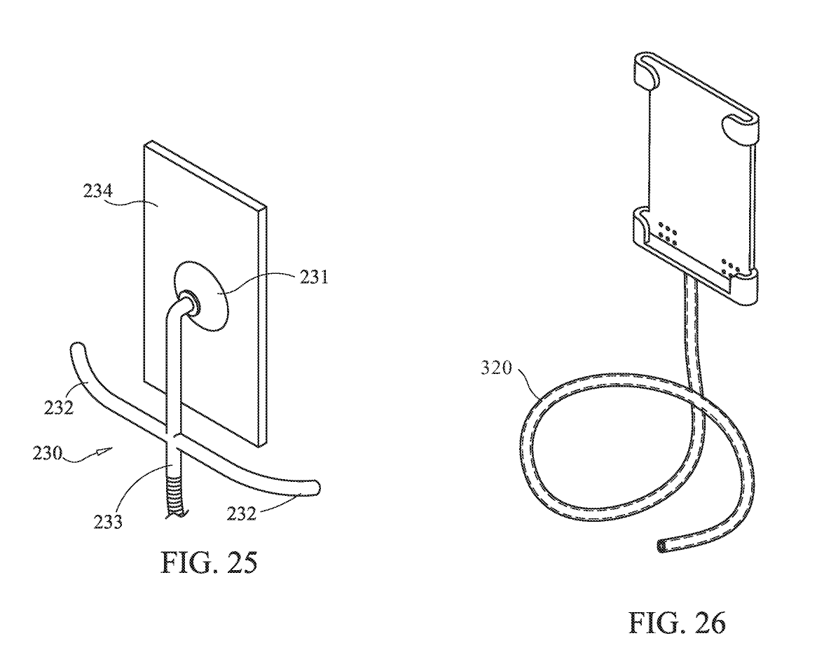

An alternate holder 230 is shown in FIG. 25. It attaches to the back of an ebook 234 via a suction cup portion 231. Since that attachment might not be robust enough to allow fine repositioning by grasping the ebook reader itself, handles 232 are provided at the base 233 of the holder for repositioning.

FIG. 26 shows an embodiment of a unit similar to that of FIG. 1 however, the tubes are covered with a fabric sleeve 320. Such coverings could protect the tubing and joints from sand and water when used at the beach, for example. For protection, the sleeve might be composed of polychloroprene or other synthetic rubber. Sleeves can also be decorative. Decorative sleeves can be composed of a wide variety of fabric types and patterns. Other versions might have all or portions of their tubes covered with a shrink wrap tubing or coated with a protective or a decorative substance.

Those skilled in the art will be aware of materials, techniques and equipment suitable to produce the example embodiments presented as well as variations on the those examples. This teaching is presented for purposes of illustration and description but is not intended to be exhaustive or limiting to the forms disclosed. Many modifications and variations will be apparent to those of ordinary skill in the art. The embodiments and versions help to explain the principles of the invention, the practical application, and to enable others of ordinary skill in the art to understand it. Various embodiments with various modifications as are suited to the particular application contemplated are expected.

In the following claims, the words “a” and “an” should be taken to mean “at least one” in all cases, even if the wording “at least one” appears in one or more claims explicitly. The scope of the invention is set out in the claims below.

What is claimed:

1. A reading stand for an electronic device comprising:
a holder adapted for securely accepting an electronic reading device, and
an elongated flexible tube operatively coupled to said holder proximate to a first terminus of said tube; the degree of flexibility of said tube being non-uniform along its length and having a greater degree of flexibility over an upper portion proximate to the first terminus than over a lower portion distal to the first terminus.

2. The reading stand of claim 1 wherein the length and degree of flexibility of the lower tube portion is such as to be readily, manually formable into a configuration as an upright stand of effective strength to support said holder when said holder is accommodating an electronic reading device for which it is adapted.

3. The reading stand of claim 2 wherein the length and degree of flexibility of the upper tube portion is such as to provide for ready, fine, manual repositioning support of said holder when said holder is upright.

4. The reading stand of claim 3 wherein the length and degree of flexibility of the lower tube portion is such as to further be readily, manually formable into a configuration comprising a partially coiled base portion and having no further requirement for a base structure.

5. The reading stand of claim 1 wherein the length and degree of flexibility of the lower tube portion is such as to further be readily, manually formable into a configuration comprising a partially coiled base portion and having no further requirement for a base structure.

6. The reading stand of claim 4 wherein the operative coupling is such as to provide a degree of pivotal motion between said holder and said tube axially about said tube.

7. The reading stand of claim 4 wherein the upper tube portion is between about 3″ and about 8″ in length and the lower portion is between about 45″ and about 55″ in length.

8. The reading stand of claim 1 wherein the length and degree of flexibility of the upper tube portion is such as to provide for ready, fine, manual repositioning support of said holder when said holder is upright.

9. The stand of claim 1 wherein the flexible tube comprises at least two operatively coupled sections, each section respectively of substantially uniform flexibility, at least one section being effectively more flexible than a second section.

10. The stand of claim 9 wherein said at least two sections are readily user de-coupleable and are readily user re-coupleable.

11. A holder of reading material coupled to a flexible tube wherein the flexibility of the tube is greater in a segment proximate to the coupled holder than in segments distal from the coupled holder such that the tube is readily manually configurable into a base and stand with fine manual positioning of the reading material being provided for by manipulation of the proximate segment and gross manual positioning is provided for by manipulation of distal segments.

12. The apparatus of claim 11 wherein the coupling is such as to provide for ready manual pivoting of the holder axially with respect to the proximate portion of the tube.

13. The apparatus of claim 11 wherein the length, mass, and degree of flexibility of the distal segments of the tube are such as to allow manual configuration of the tube into a partially coiled, stable base for upright supporting of the proximate portions of the tube, the holder, and the reading material for which the apparatus is adapted.

14. The apparatus of claim 12 wherein at least a portion of the tube is covered by a fabric sleeve.

15. The apparatus of claim 14 wherein the fabric sleeve is comprised of a synthetic rubber.

16. The apparatus of claim 14 wherein the fabric sleeve has a protective attribute.

17. The apparatus of claim 14 wherein the fabric sleeve has a decorative attribute.

18. A kit for a stand adapted for holding an electronic visual display for reading comprising:
a. a holder so shaped and adapted as to retain and support an electronic book, or optionally, a portable computing device;
b. a first gooseneck tube of between about 2″ and about 14″ in length being readily, operatively, coupleable to said holder;
c. a second gooseneck tube between about 20″ to about 65″ in length, being readily, operatively, coupleable to said first gooseneck tube;
said first tube of effective stiffness to serve as an upright portion of a stand for said holder when holder and first tube are mutually coupled and when said holder is retaining an electronic book or a portable computing device for which said holder is adapted;
said second tube of effective length and stiffness to serve as a stand and also to serve as a base for the combination of said first gooseneck tube and said holder when said second tube is operatively coupled to said first tube and holder, and when said holder is retaining an electronic book or a portable computing device for which said holder is adapted.

19. The kit of claim 18 wherein said first tube is between about 3″ and about 8″ in length, and wherein said second tube is between about 45″ and about 55″ in length.

20. The kit for a stand of claim 18 wherein a structure providing for the operative coupleability between said holder and said first tube allows for pivoting of the major plane of said holder axially about said first tube when so coupled.

21. A stand for reading matter comprising:
means for holding the reading matter;
means for supporting said holding means;
means connecting said means for supporting to said means for holding;
said means for supporting comprising at least two elongated portions having mutually different degrees of stiffness, a portion generally more stiff being more distal from the connecting means, and a relatively less stiff portion being relatively proximate to the connecting means.

22. The stand of claim 21 wherein the more stiff portion is effectively stiff to support the load of said means for holding combined with the reading matter for which said holding means is adapted, in an upright fashion; and further, wherein the less stiff portion is effectively flexible enough for manual, fine repositioning of said holding means when upright.

23. The stand of claim 21 wherein said connecting means provides for said holding means to pivot axially about said means for supporting.

24. A method of adjusting the position of a universally positionable, elongated ebook stand comprising:
bending, by hand, a flexible portion of the stand into a configuration such that a distal portion of the flexible aspect of the stand is at least partially coiled as to provide a stable base for supporting an ebook in a holder at a proximate portion of the stand;
adjusting, by hand, the position of a flexible portion of the stand such that the holder is grossly positioned as desired for viewing;
adjusting, by hand, the position of a distinct and relatively more flexible second portion of the stand such that the holder is finely positioned as desired for viewing;
thereby readily and accurately transforming the stand into a self-standing configuration positioned as a user chooses for convenient reading.

25. The method of claim 24 further comprising: pivoting, by hand, the orientation of a major plane of the holder, axially with respect to the elongated stand.
